(19) United States
(12) Patent Application Publication
(10) Pub. No.: US 2012/0034752 A1
(43) Pub. Date: Feb. 9, 2012

(54) METHODS OF FORMING A GATE STRUCTURE AND METHODS OF MANUFACTURING A SEMICONDUCTOR DEVICE USING THE SAME

(75) Inventors: Weon-Hong KIM, Suwon-si (KR); Hyung-Suk Jung, Seoul (KR); Ha-Jin Lim, Seoul (KR)

(73) Assignee: Samsung Electronics Co., Ltd, Suwon-si (KR)

(21) Appl. No.: 13/195,521

(22) Filed: Aug. 1, 2011

(30) Foreign Application Priority Data
Aug. 3, 2010 (KR) 10-2010-0074849

(51) Int. Cl. H01L 21/336; H01L 21/02

(52) U.S. Cl. 438/381; 438/585; 257/E21.409; 257/E21.008

(57) ABSTRACT

In a method of forming a gate structure, a gate pattern including a gate insulation layer pattern and a gate electrode sequentially stacked on a substrate is formed. The gate electrode includes a metal. A first plasma process is performed on the gate pattern using a reaction gas to reduce an oxidized edge portion of the gate electrode. The reaction gas includes nitrogen. A spacer is formed on a sidewall of the gate pattern. A threshold voltage is adjusted by reducing the oxidized edge portion of the gate electrode. Therefore, a semiconductor device including the gate pattern has excellent electrical characteristics.

### CROSS-REFERENCE TO RELATED APPLICATIONS

This application claims priority under 35 USC §119 to Korean Patent Application No. 10-2010-0074849 filed on Aug. 3, 2010 in the Korean Intellectual Property Office (KIPO), the disclosure of which is herein incorporated by reference in its entirety.

### BACKGROUND OF THE INVENTION

1. Field of the Invention

Exemplary embodiments relate to methods of forming a gate structure and methods of manufacturing a semiconductor device using the same. More particularly, exemplary embodiments relate to methods of forming a gate structure that includes a gate electrode having a metal and methods of manufacturing a semiconductor device using the same.

2. Description of the Related Art

Recently, a high-k dielectric material has been used for forming a gate insulation layer and a metal has been used for forming a gate electrode instead of polysilicon. A spacer may be formed using silicon oxide on a sidewall of a gate structure that includes a gate insulation layer having a high-k dielectric material and a metal gate electrode. In this case, the sidewall of the gate structure may be oxidized to result in a narrow width effect by which a threshold voltage of the gate electrode may be increased.

The spacer may be formed using silicon nitride in order to avoid the oxidation of the gate structure. However, edge portions of the metal gate electrode may also be oxidized by a heat treatment, etc., and thus the threshold voltage of the gate electrode may be changed.

### SUMMARY OF THE INVENTION

Exemplary embodiments provide a method of forming a gate structure having excellent electrical characteristics.

Exemplary embodiments provide a method of manufacturing a semiconductor device using the method of forming the gate structure.

Additional aspects, advantages, and utilities of the present general inventive concept will be set forth in part in the description which follows and, in part, will be obvious from the description.

According to exemplary embodiments, there is provided a method of forming a gate structure. In the method, a gate pattern including a gate insulation layer pattern and a gate electrode sequentially stacked on a substrate is formed. The gate electrode includes a metal. A first plasma process is performed on the gate pattern using a reaction gas to reduce an oxidized edge portion of the gate electrode. The reaction gas includes nitrogen (N). A spacer is formed on a sidewall of the gate pattern.

The reaction gas may include ammonia (NH₃) or nitrogen (N₂) gas.

The gate electrode may include titanium (Ti) or titanium nitride.

The spacer may include silicon nitride.

In the forming the spacer, a spacer layer may be formed on the substrate to cover the gate pattern by a PEALD process. The spacer layer may be anisotropically etched.

The first plasma process and the PEALD process may be performed in-situ in the same chamber.

A second plasma process may be further performed on the spacer layer using NH₃ or N₂ gas as a reaction gas.

The first plasma process, the PEALD process and the second plasma process may be performed in-situ in the same chamber.

The PEALD process may be performed by applying a high frequency power in a range of about 200 W to about 800 W.

The PEALD process may be performed on a single wafer.

According to exemplary embodiments, there is provided a method of manufacturing a semiconductor device. In the method, a gate pattern including a gate insulation layer pattern and a gate electrode sequentially stacked on a substrate is formed. The gate electrode includes a metal. A first plasma process may be performed on the gate pattern using a reaction gas to reduce an oxidized edge portion of the gate electrode. The reaction gas includes nitrogen (N). A spacer is formed on a sidewall of the gate pattern. An impurity region is formed at an upper portion of the substrate adjacent to the gate pattern and the spacer. A capacitor electrically connected to the impurity region is formed.

In the forming the spacer, a spacer layer may be formed on the substrate to cover the gate pattern by a PEALD process. The spacer layer may be anisotropically etched.

The first plasma process and the PEALD process may be performed in-situ in the same chamber.

A second plasma process may be further performed on the spacer layer using NH₃ or N₂ gas as a reaction gas.

The first plasma process, the PEALD process and the second plasma process may be performed in-situ in the same chamber

According to exemplary embodiments, there is provided a method of manufacturing a semiconductor device. In the method, a gate pattern including a tunnel insulation layer pattern, a floating gate, a dielectric layer pattern and a control gate sequentially stacked on a substrate is formed. At least one of the floating gate and the control gate includes a metal. A first plasma process is performed on the gate pattern using NH₃ or N₂ gas as a reaction gas to reduce an oxidized edge portion of at least one of the floating gate and the control gate. A spacer is formed on a sidewall of the gate pattern.

In the forming the spacer, a spacer layer may be formed on the substrate to cover the gate pattern by a PEALD process. The spacer layer may be anisotropically etched.

The first plasma process and the PEALD process may be performed in-situ in the same chamber.

After forming the spacer layer, a second plasma process may be further performed using NH₃ or N₂ gas as a reaction gas.

According to exemplary embodiments, there is provided a method of manufacturing a semiconductor device. In the method, a gate pattern including a tunnel insulation layer pattern, a charge trapping layer pattern, a blocking layer pattern and a gate electrode sequentially stacked on a substrate is formed. The gate electrode includes a metal. A first plasma process is performed on the gate pattern using NH₃ or N₂ gas as a reaction gas to reduce an oxidized edge portion of the gate electrode. A spacer is formed on a sidewall of the gate pattern.

According to exemplary embodiments, a plasma process may be performed using NH₃ or N₂ gas as a reaction gas before forming a spacer. An edge portion of a gate electrode may be reduced by the plasma process to prevent a threshold voltage of a transistor from being changed so that operation characteristics of the transistor may be enhanced.

The foregoing and other aspects, advantages, and utilities of the present general inventive concept may be achieved by providing a semiconductor device including a substrate, a gate pattern including a gate insulation layer pattern and a gate electrode sequentially stacked on a substrate, the gate electrode including a metal, and the gate patter having a first plasma processed portion to reduce an oxidized edge portion thereof; a spacer on a sidewall of the gate pattern, an impurity region formed at an upper portion of the substrate adjacent to the gate pattern and the spacer, and a capacitor formed over the gate pattern to be electrically connected to the impurity region of the substrate.

The spacer may include a second plasma processed portion.

The gate pattern may include a plurality of sub-gate patterns, the spacer may include a plurality of sub-spacers formed on both sides of each of the sub-gate patterns, and the semiconductor may further include a plurality of plugs, at least one plug having a first portion disposed between the adjacent sub-spacers, the first portion of the one plug having a first thickness variable according to a thickness of the corresponding sub-spacer.

The one plug may have a second portion extended from the first portion, and the second portion may have a second thickness different from the first thickness.

The second portion of the one plug may be electrically connect to the capacitor

### BRIEF DESCRIPTION OF THE DRAWINGS

These and/or other aspects and advantages of the present general inventive concept will become apparent and more readily appreciated from the following description of the embodiments, taken in conjunction with the accompanying drawings of which:

FIGS. 1 to 3B are cross-sectional views illustrating a method of forming a gate structure according to exemplary embodiments of the present general inventive concept;

FIGS. 4 to 8 are cross-sectional views illustrating a method of manufacturing a semiconductor device according to exemplary embodiments of the present general inventive concept;

FIGS. 9 to 11 are cross-sectional views illustrating a method of forming a gate structure according to exemplary embodiments of the present general inventive concept; and

FIGS. 12 to 15 are cross-sectional views illustrating a method of manufacturing a semiconductor device according to exemplary embodiments of the present general inventive concept.

### DETAILED DESCRIPTION OF THE PREFERRED EMBODIMENTS

Reference will now be made in detail to the embodiments of the present general inventive concept, examples of which are illustrated in the accompanying drawings, wherein like reference numerals refer to the like elements throughout. The embodiments are described below in order to explain the present general inventive concept while referring to the figures. The present inventive concept may, however, be embodied in many different forms and should not be construed as limited to the example embodiments set forth herein. Rather, these exemplary embodiments are provided so that this description will be thorough and complete, and will fully convey the scope of the present inventive concept to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present inventive concept.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular exemplary embodiments only and is not intended to be limiting of the present inventive concept. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Exemplary embodiments are described herein with reference to cross-sectional illustrations that are schematic illustrations of idealized exemplary embodiments (and intermediate structures). As such, variations from the shapes of the illustrations as a result, for example, of manufacturing techniques and/or tolerances, are to be expected. Thus, exemplary embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present inventive concept.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, exemplary embodiments will be explained in detail with reference to the accompanying drawings.

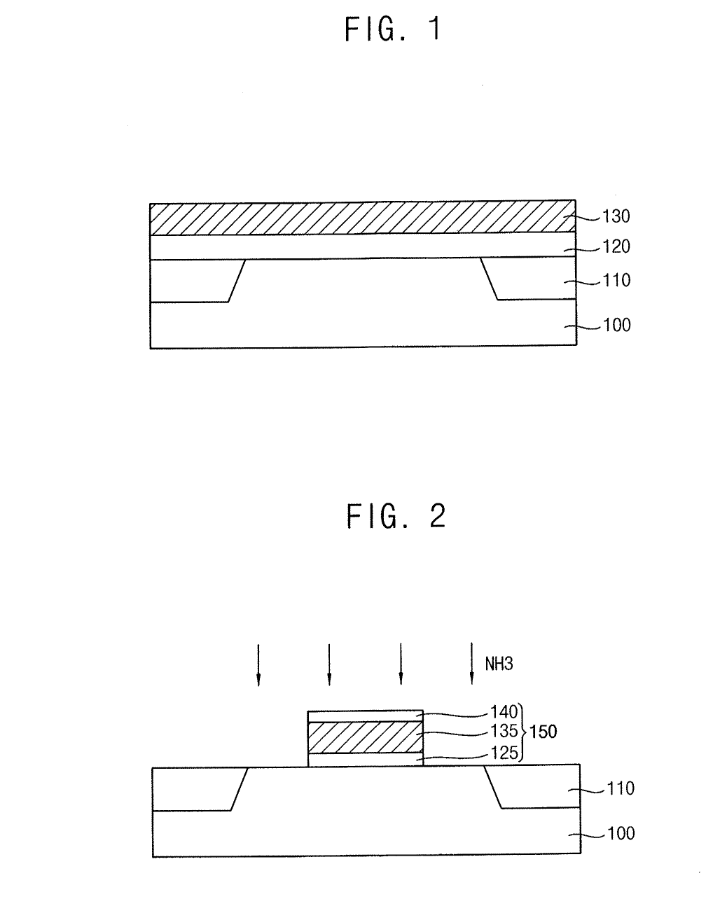

FIGS. 1 to 3 are cross-sectional views illustrating a method of forming a gate structure according to exemplary embodiments.

The method may be performed in a chamber according to an exemplary embodiment of the present general inventive concept. The chamber may be configured to perform a process of forming a semiconductor chip, a semiconductor device, etc. It is possible that the chamber can be used to perform method according to other exemplary embodiments of the present general inventive concept.

Referring to FIG. 1, a substrate 100 including a semiconductor material, such as single crystalline silicon, may be prepared. An isolation layer 110 may be formed on the substrate 100 by a shallow trench isolation (STI) process to define an active region and a field region in the substrate 100.

A gate insulation layer 120 may be formed on the substrate 100. In exemplary embodiments, the gate insulation layer 120 may be formed using a metal oxide having a high dielectric constant. For example, the metal oxide may include hafnium oxide, hafnium silicon oxide, zirconium oxide, zirconium silicon oxide, hafnium oxynitride, hafnium silicon oxynitride, zirconium oxynitride, zirconium silicon oxynitride, aluminium oxide, hafnium aluminium oxide, lanthanum oxide, hafnium lanthanum oxide, zirconium aluminium oxide, aluminium oxynitride, hafnium aluminium oxynitride, lanthanum oxinitride, hafnium lanthanum oxynitride, zirconium aluminium oxynitride, etc. These may be used alone or in a mixture thereof. Alternatively, the gate insulation layer 120 may be formed by oxidizing a top surface of the substrate 100.

A gate conductive layer 130 may be formed on the gate insulation layer 120. The gate conductive layer 130 may be formed by a chemical vapor deposition (CVD) process or a sputtering process. In exemplary embodiments, the gate conductive layer 130 may be formed using a metal, a metal silicide and/or a nitride thereof. For example, the gate conductive layer 130 may be formed using molybdenum (Mo), titanium (Ti), tantalum (Ta), hafnium (Hf), zirconium (Zr), aluminium (Al), tungsten (W), tantalum silicide, titanium silicide and/or a nitride thereof. In an exemplary embodiment, the gate conductive layer 130 may be formed to have a thickness of about 35 to about 65 Å.

Referring to FIG. 2, a gate mask 140 may be formed on the gate conductive layer 130. The gate conductive layer 130 and the gate insulation layer 120 may be sequentially patterned using the gate mask 140 as an etching mask. Accordingly, a gate pattern 150 including a gate insulation layer pattern 125, a gate electrode 135 and a gate mask 140 may be formed on the substrate 100.

An edge portion of the gate electrode 135 may be exposed to an atmosphere at a high temperature during the patterning process, and thus the edge portion of the gate electrode 135 may be oxidized to increase a work function of the gate electrode 135 and negative charges of the gate insulation layer pattern 125 and the gate electrode 135. Therefore, when the gate pattern 150 is used in a negative-channel metal oxide semiconductor (NMOS) transistor, the threshold voltage of the NMOS transistor may be increased, while when the gate pattern 150 is used in a positive-channel metal oxide semiconductor (PMOS) transistor, the threshold voltage of the PMOS transistor may be decreased.

A first plasma process may be performed on the gate pattern 150 using a reaction gas including nitrogen (N) so that the oxidized edge portion of the gate electrode 135 may be reduced. For example, the reaction gas may include ammonia (NH₃) or nitrogen (N₂) gas.

By performing the first plasma process, the increased threshold voltage of the NMOS transistor may be decreased and the decreased threshold voltage of the PMOS transistor may be increased. Additionally, oxygen vacancies that may be generated in the gate insulation layer pattern 125 may be substituted with nitrogen atoms. Accordingly, positive charges may be increased in the gate insulation layer pattern 125 so that the threshold voltage of the NMOS transistor may be further decreased.

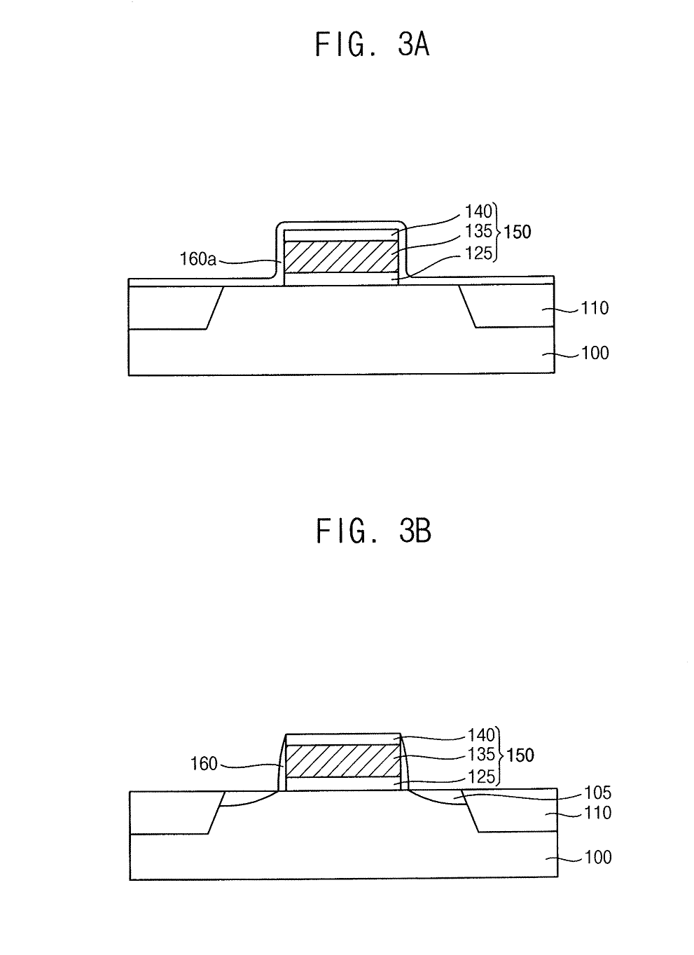

Referring to FIG. 3A, a spacer layer 160a may be formed on the substrate 100 to cover the gate pattern 150. The spacer layer may be formed using silicon nitride. Although FIG. 3A shows the spacer layer 160a covering a region above the substrate 100 and a side (or edge) portion of the gate pattern 150, it is possible that the spacer layer 160a can be formed to cover the region and a top surface of the gate pattern 150. In an exemplary embodiment, the spacer layer 160a may be formed by a plasma enhanced atomic layer deposition (PEALD) process.

In exemplary embodiments, the PEALD process may be performed on a single wafer using direct plasma so that the reduction of the oxidized edge portion of the gate electrode may be enhanced. The PEALD process may be performed by applying a high frequency power greater than about 200 W. For example, the PEALD process may be performed by applying a high frequency power in a range of about 200 to about 800 W. In an exemplary embodiment, the PEALD process may be performed at a temperature in a range of about 250 to about 500° C.

In exemplary embodiments, the first plasma process and the process for forming the spacer layer may be performed in-situ in the same chamber. Thus, the gate pattern 135 may not be exposed to an atmosphere during the formation of the spacer layer so that a sidewall of the gate pattern 135 may be prevented from being oxidized by the atmosphere.

In exemplary embodiments, a second plasma process may be further performed after forming the spacer layer 160a. The second plasma process may be performed using NH₃ or N₂ gas as a reaction gas. By performing the second plasma process, a natural oxide layer that may be formed on the spacer layer 160a may be reduced and other impurities on the spacer layer 160a may be removed

In exemplary embodiments, the first plasma process, the process for forming the spacer layer and the second plasma process may be performed in-situ in the same chamber.

Referring to FIG. 3B, the spacer layer 160a may be anisotropically etched to form a spacer 160 on the sidewall of the gate pattern 150. Accordingly, a gate structure including the gate pattern 150 and the spacer 160 may be formed on the substrate 100. The spacer 160 may have a thickness with respect to the side wall of the gate structure. The thickness may vary according to a distance from a surface of the substrate 100.

Impurities may be implanted onto the substrate 100 using the gate structure as an ion implantation mask to form an impurity region 105 at an upper portion of the substrate 100 adjacent to the gate structure. The impurity region 105 may serve as a source/drain region of a transistor including the gate structure.

The threshold voltage of the transistor including the gate pattern 150 may be changed because a sidewall of the gate electrode 135 may be oxidized during the formation of the gate pattern 150. However, in example embodiments, the oxidized sidewall of the gate electrode 135 may be reduced by the plasma process or the process for forming the spacer layer so that the threshold voltage may be changed little.

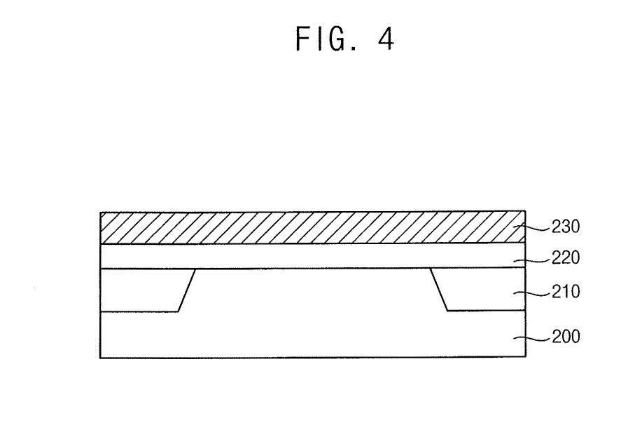

FIGS. 4 to 8 are cross-sectional views illustrating a method of manufacturing a semiconductor device according exemplary embodiments. Particularly, FIGS. 4 to 8 illustrate a method of manufacturing a dynamic random access memory (DRAM) device.

Referring to FIG. 4, a substrate 200 including a semiconductor material may be prepared. For example, the substrate 200 may include single-crystalline silicon. An isolation layer 210 may be formed on the substrate 200 by an STI process to define an active region and a field region in the substrate 200.

A gate insulation layer 220 and a gate conductive layer 230 may be sequentially formed on the substrate 200 by performing a process substantially the same as or similar to that illustrated with reference to FIG. 1.

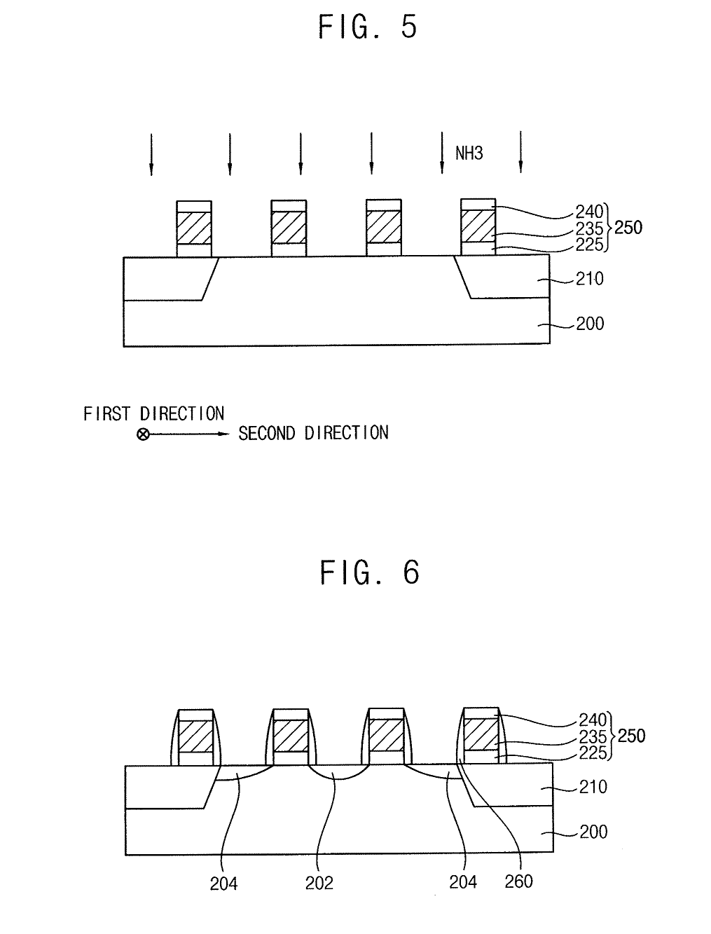

Referring to FIG. 5, a process substantially the same as or similar to that illustrated with reference to FIG. 2 may be performed. A gate mask 240 may be formed on the gate conductive layer 230, and the gate conductive layer 230 and the gate insulation layer 220 may be sequentially and partially removed using the gate mask 240 as an etching mask. Accordingly, a plurality of gate patterns 250 each of which includes a gate insulation layer pattern 225, a gate electrode 235 and a gate mask 240 sequentially stacked on the substrate 200 may be formed. In exemplary embodiments, the gate patterns 250 may extend in a first direction and may be spaced apart from one another in a second direction perpendicular to the first direction.

A first plasma process may be performed on the gate pattern 250 using a reaction gas including nitrogen (N) so that an oxidized sidewall of the gate electrode 235 may be reduced. Accordingly, a threshold voltage of a transistor including the gate pattern 250 may be adjusted into a desirable level. For example, the reaction gas may include NH₃ or N₂ gas.

Referring to FIG. 6, a process substantially the same as or similar to that illustrated with reference to FIGS. 3A and 3B may be performed. A spacer layer (not shown) may be formed on the substrate 200 to cover the gate pattern 250. The spacer layer may be anisotropically etched to form a spacer 260 on the sidewall of the gate pattern 250. Accordingly, a gate structure including the gate pattern 250 and the spacer 260 may be formed on the substrate 200.

The spacer layer may be formed using silicon nitride by a PEALD process. The PEALD process may be performed on a single wafer using direct plasma. The first plasma process and the process for forming the spacer layer may be performed in-situ in the same chamber. A second plasma process may be further performed after forming the spacer layer. The first plasma process, the process for forming the spacer layer and the second plasma process may be performed in-situ in the same chamber.

Impurities may be implanted onto the substrate 200 using the gate structures as an ion-implanting mask to form first and second impurity regions 202 and 204 at upper portions of the substrate 200 adjacent to the gate structures. Transistors may be defined by the gate structures and the impurity regions 202 and 204.

Referring to FIG. 7, a first insulating interlayer 270 may be formed on the substrate 200 to cover the transistors. The first insulating interlayer 270 may be partially removed to form first and second contact holes 270a1 and 270a2 that expose the first and second impurity regions 202 and 204, respectively. A conductive layer may be formed on the substrate 200 and the first insulating interlayer 270 to fill the first and second contact holes 270a1 and 270a2. An upper portion of the conductive layer may be planarized until a top surface of the first insulating interlayer 270 is exposed to form first and second plugs 282 and 284 electrically connected to the first and second impurity regions 202 and 204, respectively.

A second insulating interlayer 290 may be formed on the first insulating interlayer 270 and the first and second plugs 282 and 284. The second insulating interlayer 290 may be partially removed to form a third contact hole 290a that may expose a top surface of the second plug 284. A conductive layer may be formed on the second plug 284 and the second insulating interlayer 290, and planarized until a top surface of the second insulating interlayer 290 is exposed. Accordingly, a bit line contact (not shown) may be formed to be electrically connected to the first plug 282.

A bit line (not shown) contacting the bit line contact may be formed on the second insulating interlayer 290. In example embodiments, the bit line may be formed to extend in the second direction. The bit line may be formed using a metal, a conductive metal nitride or doped polysilicon. A third insulating interlayer 300 may be formed on the second insulating interlayer 290 to cover the bit line.

The second and third insulating interlayers 290 and 300 may be partially etched to form a fourth contact hole (not shown) that exposes a top surface of the second plug 284. A conductive layer may be formed on the second plug 284 and the third insulating interlayer 300 to fill the fourth contact hole. An upper portion of the conductive layer may be planarized until a top surface of the third insulating interlayer 300 is exposed to form a capacitor contact 310 that is electrically connected to the second plug 284.

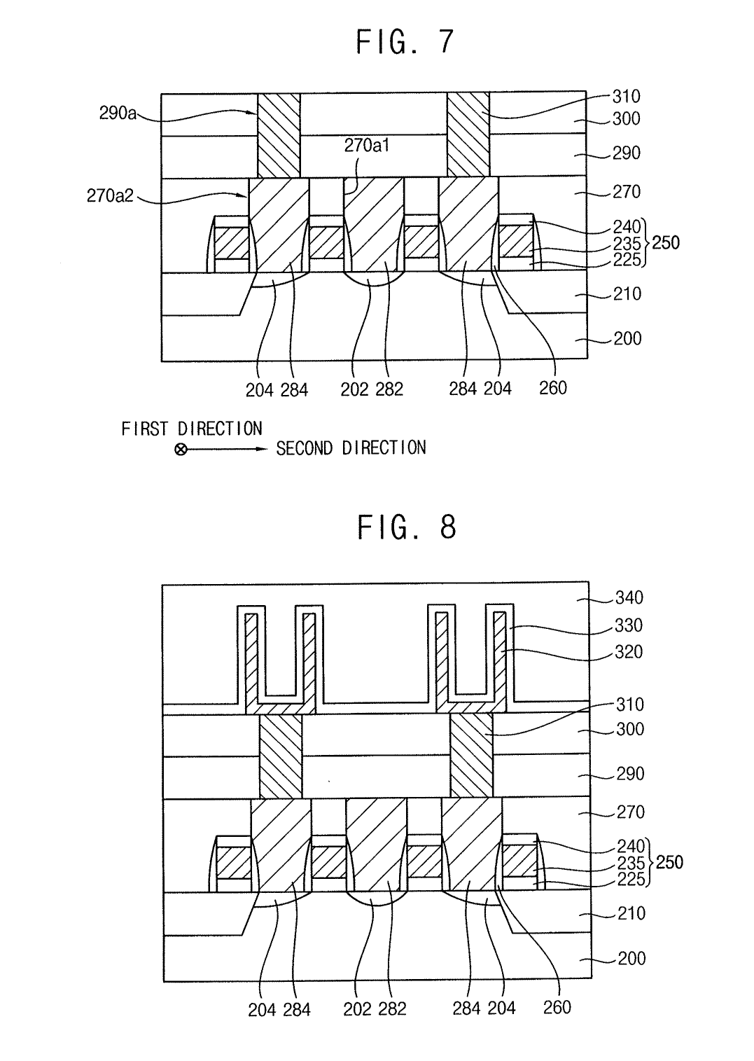

Referring to FIG. 8, an etch-stop layer (not shown) and a mold layer (not shown) may be formed on the third insulating interlayer 300. The mold layer and the etch-stop layer may be partially removed to form an opening (not shown) that exposes a top surface of the capacitor contact 310.

A lower electrode layer may be formed on an inner wall of the opening and a top surface of the mold layer. The lower electrode layer may be formed using a metal or a metal nitride, e.g., titanium, titanium nitride, tantalum, tantalum nitride, tungsten nitride etc., or doped polysilicon. A sacrificial layer may be formed on the lower electrode layer, and then the sacrificial layer and the lower electrode layer may be partially removed to expose a top surface of the mold layer. The sacrificial layer and the mold layer may be removed to form a lower electrode 320 that is electrically connected to the capacitor contact 310.

A dielectric layer 330 may be formed on the etch-stop layer and the third insulating interlayer 300 to cover the lower electrode 320. The dielectric layer 330 may be formed using a material having a higher dielectric constant than that of silicon nitride or silicon oxide.

An upper electrode 340 may be formed on the dielectric layer 330. The upper electrode may be formed using a metal and/or a metal nitride such as titanium nitride, tantalum nitride, tungsten nitride, ruthenium, etc., thereby forming a capacitor that includes the lower electrode 320, the dielectric layer 330 and the upper electrode 340.

By performing the processes illustrated above, a DRAM device including the gate structures and the capacitors may be manufactured.

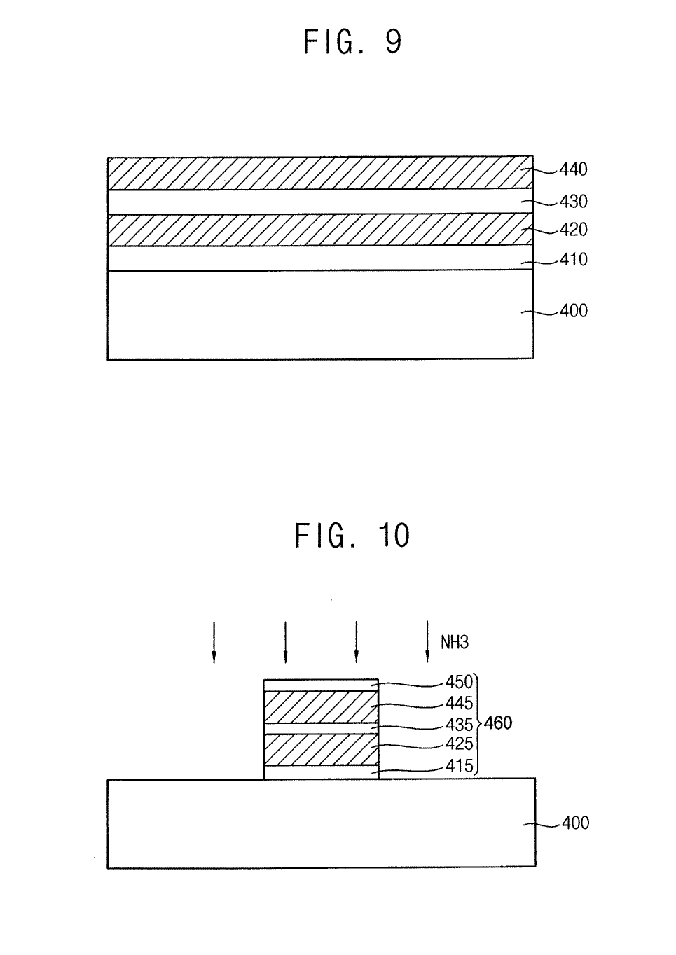

FIGS. 9 to 11 are cross-sectional views illustrating a method of forming a gate structure according to exemplary embodiments. FIGS. 9 to 11 illustrate a method of forming a gate structure of a floating gate type flash memory device.

Referring to FIG. 9, a tunnel insulation layer 410, a floating gate layer 420, a dielectric layer 430 and a control gate layer 440 may be sequentially formed on a substrate 400.

The tunnel insulation layer 410 may be formed using an oxide such as silicon oxide, a nitride such as silicon nitride or a metal oxide by a CVD process, an atomic layer deposition (ALD) process, a sputtering process, etc. Alternatively, the tunnel insulation layer 410 may be formed by performing a thermal oxidation process on the substrate 400.

The floating gate layer 420 may be formed using doped polysilicon and/or a metal having a high work function such as tungsten, titanium, cobalt, nickel, etc., by a CVD process, an ALD process or a sputtering process.

The dielectric layer 430 may be formed using a high-k dielectric material such as aluminium oxide, hafnium oxide, lanthanum oxide, lanthanum aluminium oxide, lanthanum hafnium oxide, hafnium aluminium oxide, titanium oxide, tantalum oxide or zirconium oxide by a CVD process, an ALD process or a sputtering process.

The control gate layer 440 may be formed using polysilicon and/or a metal or a metal nitride such as titanium, titanium nitride, tantalum, tantalum nitride by a CVD process, an ALD process or a sputtering process.

Alternatively, a tunnel insulation layer, a charge trapping layer, a blocking layer and a gate electrode layer may be sequentially formed on the substrate 400. In this case, a gate structure of a charge trapping type flash memory device may be formed on the substrate 400.

The charge trapping layer may be formed using a nitride such as silicon nitride or an oxide such as hafnium oxide and hafnium silicon oxide by a CVD process, an ALD process or a sputtering process. The blocking layer and the gate electrode layer may be formed by processes substantially the same as or similar to those for forming the dielectric layer 430 and the control gate layer 440, respectively.

Hereinafter, only a method of manufacturing a floating gate type flash memory device will be explained, as an example.

Referring to FIG. 10, a hard mask 450 may be formed on the control gate layer 440, and the control gate layer 440, the dielectric layer 430, the floating gate layer 420 and the tunnel insulation layer 410 may be sequentially and partially etched to form a gate pattern 460. The gate pattern 460 may include a tunnel insulation layer pattern 415, a floating gate 425, a dielectric layer pattern 435, a control gate 445 and the hard mask 450 sequentially stacked on the substrate 400.

An edge portion of the floating gate 425 and the control gate 445 may be oxidized during the patterning process or by being exposed to an atmosphere at a high temperature. Thus, a work function of the floating gate 425 and the control gate 445 and a threshold voltage of a transistor including the gate pattern 460 may be changed.

A first plasma process may be performed using a reaction gas that includes nitrogen to reduce the oxidized edge portion of the floating gate 425 and the control gate 445. Accordingly, the work function of the floating gate 425 and the control gate 445 and the threshold voltage of the transistor may be adjusted to a desirable level.

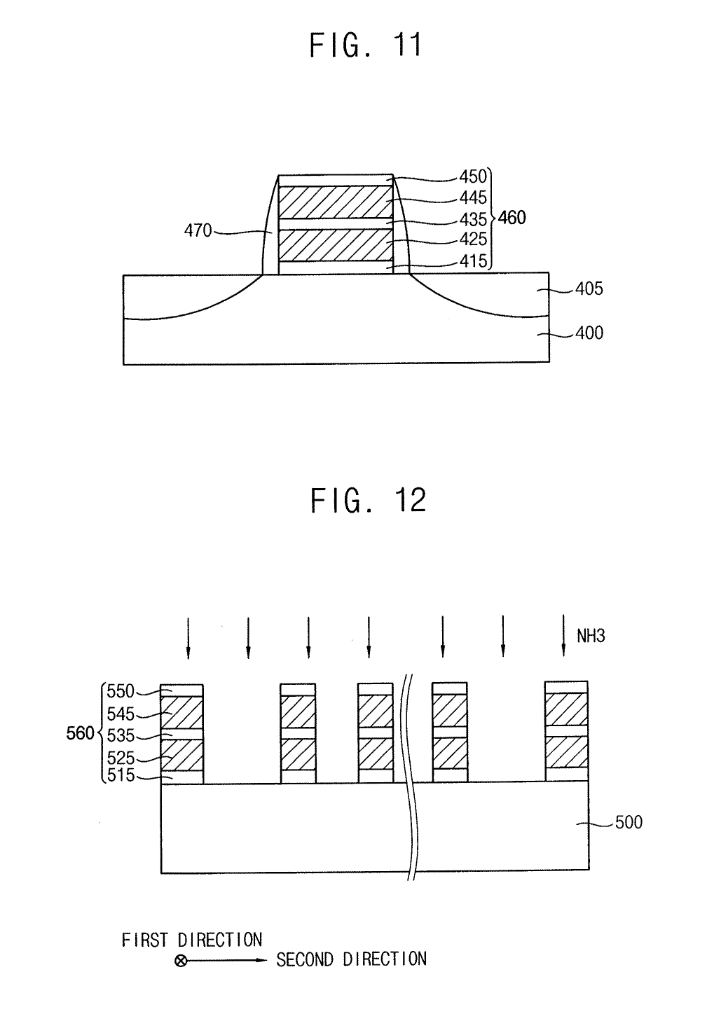

Referring to FIG. 11, a spacer 470 may be formed on a sidewall of the gate pattern 460 by performing a process substantially the same as or similar to that illustrated with reference to FIG. 3. Thus, a gate structure including the gate pattern 460 and the spacer 470 may be formed on the substrate 400. A second plasma process may be further performed after forming a spacer layer. The first plasma process, the process for forming the spacer layer and the second plasma process may be performed in-situ in the same chamber.

Impurities may be implanted onto the substrate 400 by an ion implantation process using the gate structure as an ion implantation mask to form an impurity region at an upper portion of the substrate 400 adjacent to the gate structure.

FIGS. 12 to 15 are cross-sectional views illustrating a method of manufacturing a semiconductor device according to exemplary embodiments. FIGS. 12 to 15 illustrate a method of manufacturing a flash memory device, for example.

Referring to FIG. 12, a plurality of a gate patterns 560 may be formed on the substrate 500 by performing processes substantially the same as those illustrated with reference to FIGS. 9 and 10. The gate pattern 560 may be used for a floating gate type or a charge trapping type flash memory device. In case of the floating gate type flash memory device, the gate pattern 560 may include a tunnel insulation layer pattern 515, a floating gate 525, a dielectric layer pattern 535, a control gate 545 and a hard mask 550 sequentially stacked on the substrate 500. In case of the charge trapping type flash memory device, the gate pattern 560 may include a tunnel insulation layer pattern 515, a charge trapping layer pattern 525, a blocking layer pattern 535, a gate electrode 545 and a hard mask 550. Hereinafter, only a method of manufacturing the floating gate type flash memory device will be explained, as an example. Each of gate patterns 560 may be formed to extend in a first direction and be spaced apart from one another in a second direction perpendicular to the first direction.

A plurality of gate patterns 560 may form a string including cell gate patterns, a ground selection line (GSL) and a string selection line (SSL). The string may include a plurality of cell gate patterns, e.g., 16 or 32 cell gate patterns. The GSL may be formed at one end of the string and the SSL may be formed at the other end of the string.

A process substantially the same as or similar to that illustrated with reference to FIG. 2 may be performed. Specifically, a first plasma process may be performed using a reaction gas such as NH₃ or N₂ gas.

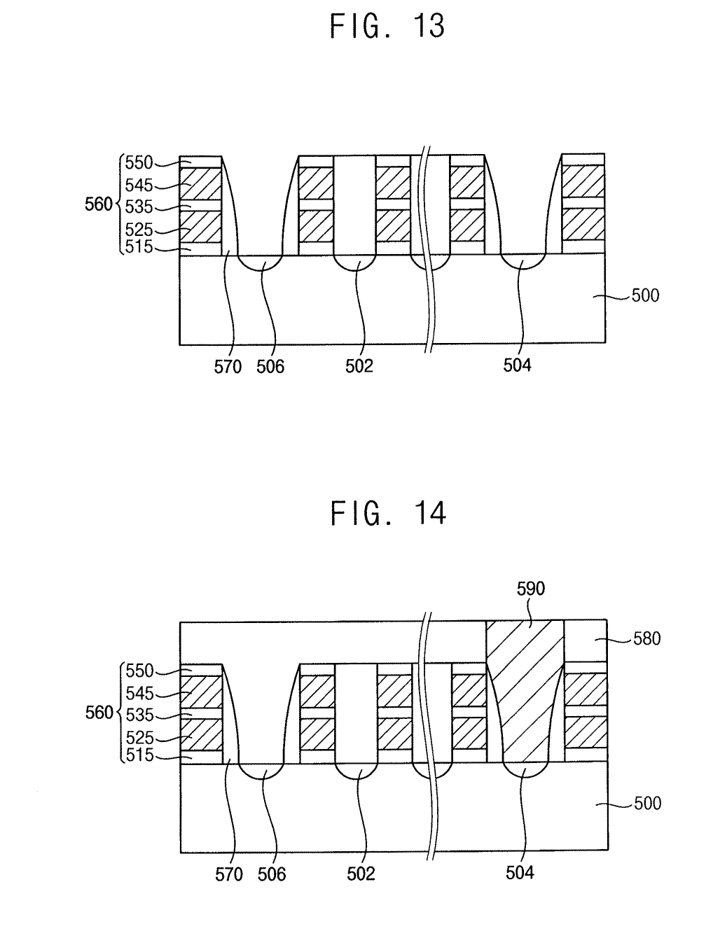

Referring to FIG. 13, a process substantially the same as or similar to that illustrated with reference to FIG. 3 may be performed. That is, a spacer layer (not shown) may be formed on the substrate 500 to cover the gate patterns 560, and the spacer layer may be anisotropically etched to form a spacer 570 on sidewalls of the gate patterns. Accordingly, a plurality of gate structures each of which includes the gate pattern 560 and the spacer 570 may be formed on the substrate 500.

The spacer layer may be formed using silicon nitride by a PEALD process. The PEALD process may be performed on a single wafer using direct plasma. The first plasma process and the process for forming the spacer layer may be performed in-situ in the same chamber. A second plasma process may be further performed after forming the spacer layer. In this case, the first plasma process, the process for forming the spacer layer and the second plasma process may be performed in-situ in the same chamber.

Impurities may be implanted onto the substrate 500 by an ion implantation process using the gate structures as an ion implantation mask to form first, second and third impurity regions 502, 504 and 506 at upper portions of the substrate 500 adjacent to the gate structures.

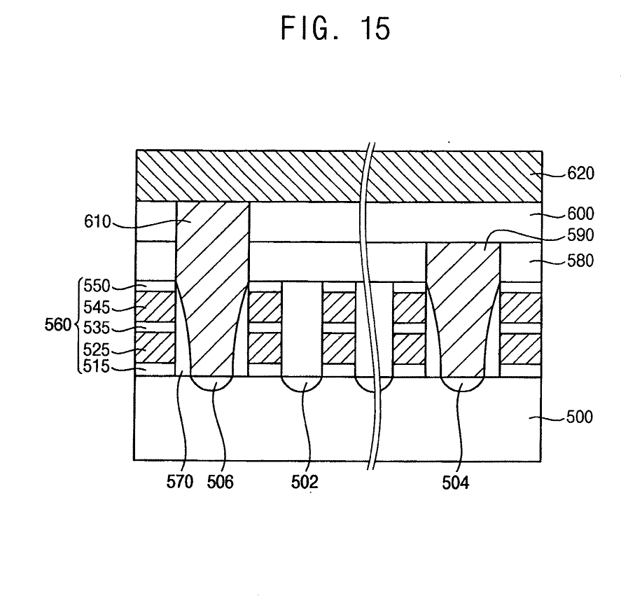

Referring to FIG. 14, a first insulating interlayer 580 may be formed on the substrate 500 to cover the gate structure. The first insulating interlayer 580 may be formed using an oxide such as BPSG, USG and SOG by a CVD process, an ALD process or a sputtering process.

The first insulating interlayer 580 may be partially removed to form a first opening (not shown) therethrough. The first opening may expose the second impurity region 504. A first conductive layer may be formed on the substrate 500 and the first insulating interlayer 580. The first conductive layer may be formed using doped polysilicon, a metal or a metal silicide. An upper portion of the first conductive layer may be planarized until a top surface of the first insulating interlayer 580 is exposed to form a common source line (CSL) 590 that fills the first opening to be electrically connected to the second impurity region 504.

Referring to FIG. 15, a second insulating interlayer 600 may be formed on the first insulating interlayer 580 and the CSL 590. The second insulating interlayer 600 may be formed using an oxide such as BPSG, USG and SOG by a CVD process, an ALD process or a sputtering process.

The first and second insulating interlayers 580 and 600 may be partially removed to form a second opening (not shown) that exposes the third impurity region 506. A second conductive layer may be formed on the substrate 500 and the second insulating interlayer 600 to fill the second opening. The second conductive layer may be formed using doped polysilicon, a metal or a metal silicide. An upper portion of the second conductive layer may be planarized until a top surface of the second insulating interlayer 600 is exposed to form a bit line contact 610 that fills the second opening to be electrically connected to the third impurity region.

A third conductive layer may be formed on the second insulating interlayer 600 and patterned to form a bit line 620. The bit line 620 may be formed to extend in the second direction and to be electrically connected to the bit line contact 620. The third conductive layer may be formed using doped polysilicon, a metal or a metal silicide.

By performing the processes illustrated above, a flash memory device according to exemplary embodiments may be manufactured.

The foregoing is illustrative of exemplary embodiments and is not to be construed as limiting thereof. Although a few exemplary embodiments have been described, those skilled in the art will readily appreciate that many modifications are possible in the exemplary embodiments without materially departing from the novel teachings and advantages of the present inventive concept. Accordingly, all such modifications are intended to be included within the scope of the present inventive concept as defined in the claims. In the claims, means-plus-function clauses are intended to cover the structures described herein as performing the recited function and not only structural equivalents but also equivalent structures. Therefore, it is to be understood that the foregoing is illustrative of various exemplary embodiments and is not to be construed as limited to the specific exemplary embodiments disclosed, and that modifications to the disclosed exemplary embodiments, as well as other exemplary embodiments, are intended to be included within the scope of the appended claims.

1. A method of forming a gate structure, the method comprising:
forming a gate pattern including a gate insulation layer pattern and a gate electrode sequentially stacked on a substrate, the gate electrode including a metal;
performing a first plasma process on the gate pattern using a reaction gas to reduce an oxidized edge portion of the gate electrode, the reaction gas including nitrogen (N); and
forming a spacer on a sidewall of the gate pattern.

2. The method of claim 1, wherein the reaction gas includes ammonia (NH₃) or nitrogen (N₂) gas.

3. The method of claim 1, wherein the gate electrode includes titanium (Ti) or titanium nitride.

4. The method of claim 1, wherein the spacer includes silicon nitride.

5. The method of claim 1, wherein forming the spacer includes:
forming a spacer layer on the substrate to cover the gate pattern by a plasma enhanced atomic layer deposition (PEALD) process; and
anisotropically etching the spacer layer.

6. The method of claim 5, wherein the first plasma process and the PEALD process are performed in-situ in the same chamber.

7. The method of claim 5, further comprising performing a second plasma process on the spacer layer using NH₃ or N₂ gas as a reaction gas.

8. The method of claim 7, wherein the first plasma process, the PEALD process and the second plasma process are performed in-situ in the same chamber.

9. The method of claim 5, wherein the PEALD process is performed by applying a high frequency power in a range of about 200 W to about 800 W.

10. The method of claim 5, wherein the PEALD process is performed on a single wafer.

11. A method of manufacturing a semiconductor device, the method comprising:
forming a gate pattern including a gate insulation layer pattern and a gate electrode sequentially stacked on a substrate, the gate electrode including a metal;
performing a first plasma process on the gate pattern using a reaction gas to reduce an oxidized edge portion of the gate electrode, the reaction gas including nitrogen (N);
forming a spacer on a sidewall of the gate pattern;
forming an impurity region at an upper portion of the substrate adjacent to the gate pattern and the spacer; and
forming a capacitor electrically connected to the impurity region.

12. The method of claim 11, wherein forming the spacer includes:
forming a spacer layer on the substrate to cover the gate pattern by a PEALD process; and
anisotropically etching the spacer layer.

13. The method of claim 12, wherein the first plasma process and the PEALD process are performed in-situ in the same chamber.

14. The method of claim 12, further comprising performing a second plasma process on the spacer layer using NH₃ or N₂ gas as a reaction gas.

15. The method of claim 14, wherein the first plasma process, the PEALD process and the second plasma process are performed in-situ in the same chamber

16-20. (canceled)
